(19) United States
(12) Patent Application Publication
(10) Pub. No.: US 2026/0231586 A1
(43) Pub. Date: Aug. 6, 2026

(54) Display Apparatus Having Light-Emitting Devices and Pixel Lenses

(71) Applicant: LG Display Co., Ltd., Seoul (KR)

(72) Inventors: A Ra Yoon, Paju-si (KR); Yong Ku Lee, Paju-si (KR); Dae Heung Lee, Paju-si (KR); Young Bok Lee, Paju-si (KR)

(21) Appl. No.: 19/442,293

(22) Filed: Jan. 7, 2026

(30) Foreign Application Priority Data
Jan. 31, 2025 (KR) 10-2025-0012647

(51) Int. Cl. H10H 29/855; H10H 29/37; H10H 29/85

(52) U.S. Cl. CPC H10H 29/855; G02B 3/0006; G09F 9/301; H10H 29/37; H10H 29/8517; H10K 50/844; H10K 50/858; H10K 59/12; H10K 59/38

(57) ABSTRACT

A display apparatus including light-emitting devices and pixel lenses is provided. The display apparatus comprises a non-zero curvature display panel including pixel areas, which generates an image provided to a user. The light-emitting devices and the pixel lenses are disposed in the pixel areas. A distance between the center of the light-emitting device and the center of the pixel lens on each pixel area is determined by a distance between the center of the display panel and the center of the light-emitting device along the surface of the display panel. Therefore, light emitted from the light-emitting device of each pixel area through the pixel lens of the corresponding pixel area is parallel to light emitted from the light-emitting device of adjacent pixel area through the pixel lens of adjacent pixel area. Thus, image distortion according to a viewing angle due to the curvature of the display panel is improved.

### CROSS-REFERENCE TO RELATED APPLICATIONS

This application claims the priority under 35 U.S.C. § 119(a) to the Republic of Korea Patent Application No. 10-2025-0012647, filed on Jan. 31, 2025, the entire contents of which are hereby expressly incorporated by reference into the present application.

### TECHNICAL FIELD

The present disclosure relates to a display apparatus in which light-emitting devices and pixel lenses are stacked on pixel areas.

### BACKGROUND

Generally, a display apparatus provides an image to a user. For example, the display apparatus can include a display panel generating the image. The display panel can include light-emitting devices on a device substrate having a curvature and pixel lenses disposed on the light-emitting devices. Each of the light-emitting devices can emit light displaying a specific color. For example, each of the light-emitting devices can include a light-emitting unit disposed between a first electrode and a second electrode. Light emitted from each light-emitting device can be provided to the user through one of the pixel lenses.

### SUMMARY

Accordingly, the present disclosure is directed to a display apparatus that substantially obviates one or more problems due to limitations and disadvantages of the related art.

An object of the present disclosure is to provide a display apparatus capable of reducing the distortion of the image provided to user by the display panel according to a viewing angle.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a display panel having a non-zero curvature. The display panel includes a light-emitting device and a pixel lens stacked in each pixel area. A distance between the center of the light-emitting device and the center of the pixel lens in each pixel area along a surface of the display panel is determined by a distance between the center of the display panel and the center of the light-emitting device along the surface of the display panel so that the light emitted from the light-emitting device in the pixel area through the pixel lens is parallel to the light emitted from a light-emitting device in an adjacent pixel area adjacent to the pixel area through a pixel lens of the adjacent pixel area. Another display apparatus according to the present disclosure comprises: a display panel including a light-emitting device and a pixel lens stacked in each pixel area, the display panel having a non-zero curvature, wherein, for a plurality of light-emitting devices of the display panel, a first distance increases with the increase of a second distance, wherein a first distance is a distance between a center of the light-emitting device and a center of the pixel lens of the light-emitting device along a surface of the display panel; and wherein a second distance is a distance between a center of the display panel and the center of the light-emitting device along a surface of the display panel. The pixel lens of the light-emitting device is positioned such that that the light emitted from the light-emitting device in the pixel area through the pixel lens is parallel to the light emitted from a light-emitting device in an adjacent pixel area adjacent to the pixel area through a pixel lens of the adjacent pixel area.

The display panel can include a device substrate supporting the light-emitting device and the pixel lens of each pixel area. The device substrate can have a curvature. A central angle θ, between the center of the display panel and the center of the light-emitting device in each pixel area, with respect to a curvature center of the curvature, and a first angle θ1, between a connecting line between the center of the light-emitting device and the center of the pixel lens in the pixel area and a virtual line passing through the center of the light-emitting device and perpendicular to an upper surface of the device substrate, can satisfy a following equation:

$${θ}_{1} = asin ( \frac{1}{{n}_{1}} sin θ ) \qquad [ equation ]$$

wherein, n1 is a refractive index of the pixel lens in the pixel area.

A lens planarization layer can be disposed on the pixel lens of each pixel area. The lens planarization layer can have a refractive index smaller than the pixel lens of each pixel area.

An encapsulation structure can be disposed between the light-emitting device and the pixel lens of each pixel area. A difference in refractive index between the pixel lens of each pixel area and the encapsulation structure can be smaller than a difference in refractive index between the pixel lens of each pixel area and the lens planarization layer.

A color filter can be disposed on the pixel lens of each pixel area. A difference in refractive index between the color filter of each pixel area and the lens planarization layer can be smaller than a difference in refractive index between the pixel lens of each pixel area and the lens planarization layer.

The display panel includes a central pixel area at the center of the display panel and non-central pixel areas not located at the center of the display panel. For each of the non-central pixel areas, a center of the color filter on the non-central pixel area can be spaced apart from a virtual line passing through a center of an emitting device of the non-central pixel area and a center of the pixel lens of the non-central pixel area.

A filter planarization layer can be disposed on the lens planarization layer. The color filter of each pixel area can be covered by the filter planarization layer. A difference in refractive index between the color filter of each pixel area and the filter planarization layer can be smaller than a difference in refractive index between the pixel lens of each pixel area and the lens planarization layer.

A refractive index of the filter planarization layer can be the same as a refractive index of the lens planarization layer.

An emission area can be defined in each pixel area by a bank insulating layer. A barrier pattern can be disposed on the bank insulating layer. The light-emitting device and the pixel lens of each pixel area can overlap with the emission area of the corresponding pixel area.

The barrier pattern can be disposed on a same layer as the pixel lens of each pixel area. The barrier pattern can be disposed on a same layer as the color filter of each pixel area.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure.

FIG. 2 is a view schematically showing a display apparatus according to an embodiment of the present disclosure.

FIG. 3 is a view showing a driving circuit of a pixel area in a display panel of the display apparatus according to the embodiment of the present disclosure.

FIG. 4 is an enlarged view of K1 region in FIG. 2.

FIG. 5 is an enlarged view of K2 region in FIG. 2.

FIG. 6 is a view showing the display apparatus according to another embodiment of the present disclosure.

FIG. 7 is a view showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical field of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly defined herein.

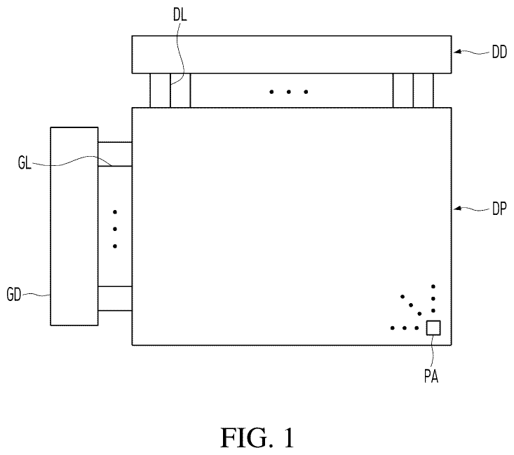

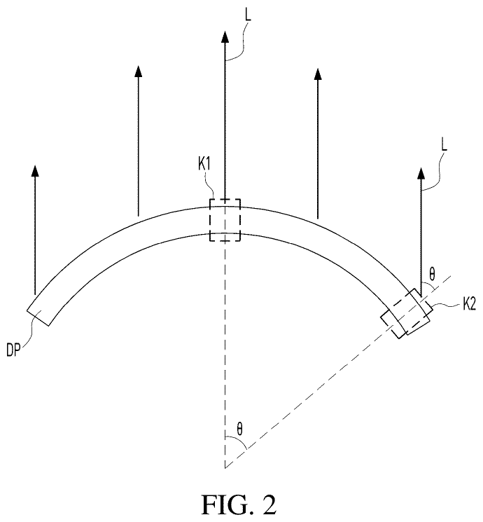

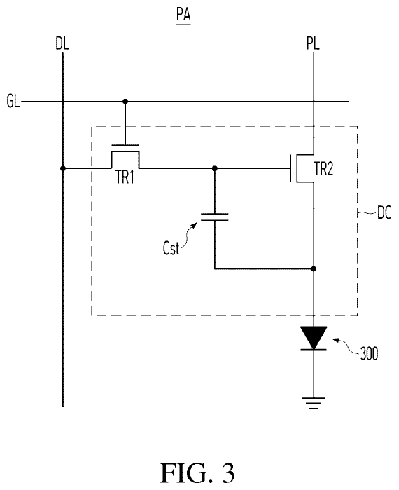

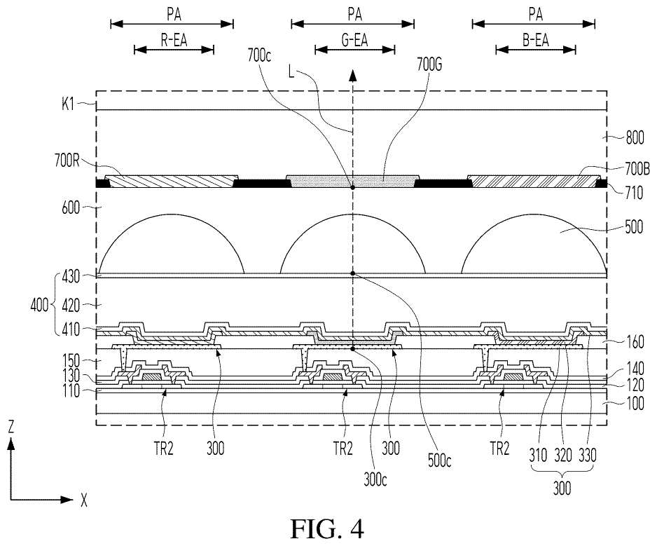

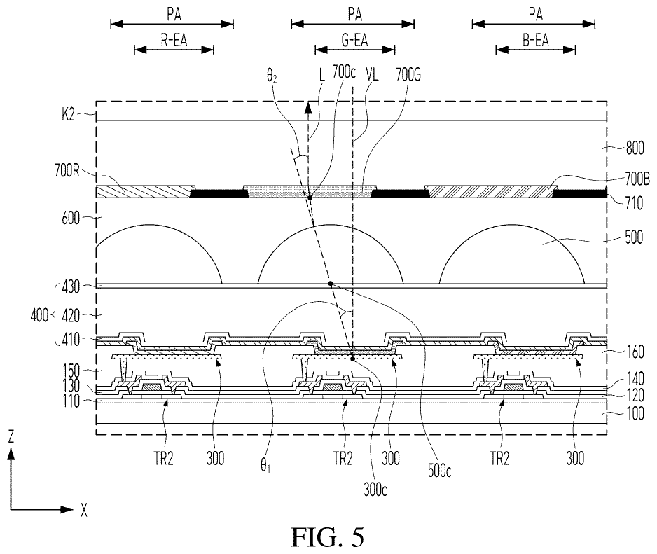

FIGS. 1 and 2 are a view schematically showing a display apparatus according to an embodiment of the present disclosure. FIG. 3 is a view showing a driving circuit of a pixel area in a display panel of the display apparatus according to the embodiment of the present disclosure. FIG. 4 is an enlarged view of K1 region in FIG. 2. FIG. 5 is an enlarged view of K2 region in FIG. 2.

Referring to FIGS. 1 to 5, the display apparatus according to the embodiment of the present disclosure can include a display panel DP. The display panel DP can generate an image provided to a user. For example, the display panel DP can include pixel areas PA. The display panel DP can have a curved shape (i.e., have a non-zero curvature). For example, a cross-section of the display panel DP can have a fan shape. For example, the display panel DP shown in FIG. 1 corresponds to the projection of the curved display panel in the XY plane, and the display panel DP in FIG. 2 corresponds to the cross-section of the curved display panel parallel to the XZ plane (e.g., a horizontal plane), wherein the X axis, Y axis, and Z axis are perpendicular to each other.

Each of the pixel areas PA can realize a specific color. For example, each of the pixel areas PA can be one of a red pixel area R-PA realizing a red color, a green pixel area G-PA realizing a green color and a blue pixel area B-PA realizing a blue color. Various signals can be applied to each pixel area PA through signal wirings GL, DL and PL. For example, a driving circuit DC electrically connected to the signal wirings GL, DL and PL and a light-emitting device 300 electrically connected to the driving circuit DC can be disposed in each pixel area PA.

The signal wirings GL, DL and PL can include a gate line GL applying a gate signal, a data line DL applying a data signal, and a power voltage supply line PL supplying a first power voltage. For example, the driving circuit DC can supply a driving current corresponding to the data signal to the light-emitting device 300 according to the gate signal using the first power voltage. The driving current supplied to the light-emitting device 300 by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The second thin film transistor TR2 can generate the driving current according to the data signal using the first power voltage. For example, the second thin film transistor TR2 can function as a driving thin film transistor. The operation of the second thin film transistor TR2 can be maintained for one frame by the storage capacitor Cst. For example, the storage capacitor Cst can be electrically connected to a gate electrode and a source electrode of the second thin film transistor TR2.

The driving circuit DC of each pixel area PA can be supported by a device substrate 100. The device substrate 100 can include an insulating material. For example, the device substrate 100 can include glass or plastic. The device substrate 100 can have a curved shape. For example, the device substrate 100 can have a same curvature as the display panel DP. At least one insulating layers 110, 120, 130, 140, 150 and 160 for preventing unintended electrical connection can be disposed on the device substrate 100. For example, a buffer insulating layer 110, a gate insulating layer 120, an interlayer insulating layer 130, a device passivation layer 140, a device planarization layer 150 and a bank insulating layer 160 can be disposed on the device substrate 100.

The buffer insulating layer 110 can be disposed on the device substrate 100. The gate insulating layer 120 can be disposed on the buffer insulating layer 110. The interlayer insulating layer 130 can be disposed on the gate insulating layer 120. The device passivation layer 140 can be disposed on the interlayer insulating layer 130. The buffer insulating layer 110, the gate insulating layer 120, the interlayer insulating layer 130 and the device passivation layer 140 can include insulating material. The driving circuit DC of each pixel area PA can be disposed between the buffer insulating layer 110 and the device passivation layer 140. For example, the damage of the driving circuit DC in each pixel area PA due to external impact and moisture can be prevented by the device passivation layer 140.

The device planarization layer 150 can be disposed on the device passivation layer 140. The device planarization layer 150 can include an insulating material. The device planarization layer 150 can include a material having a higher fluidity than the buffer insulating layer 110, the gate insulating layer 120, the interlayer insulating layer 130 and the device passivation layer 140. For example, the buffer insulating layer 110, the gate insulating layer 120, the interlayer insulating layer 130 and the device passivation layer 140 can be an inorganic insulating layer made of an inorganic insulating material, and the device planarization layer 150 can be an organic insulating layer made of an organic insulating material. A thickness difference due to the driving circuit DC of each pixel area PA can be removed by the device planarization layer 150. An upper surface of the device planarization layer 150 opposite to the device substrate 100 can be parallel to an upper surface of the device substrate 100 covered by the buffer insulating layer 110. For example, the upper surface of the device planarization layer 150 can have a curvature.

The light-emitting device 300 of each pixel area PA can be disposed on the device planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the device planarization layer 150.

The first electrode 310 and the second electrode 330 can include a conductive material. The second electrode 330 can include a different material from the first electrode 310. For example, a transmittance of the second electrode 330 can be higher than a transmittance of the first electrode 310. The first electrode 310 can have a higher reflectance than the second electrode 330. For example, the first electrode 310 can be a reflective electrode including a metal, such as aluminum (Al) and silver (Ag), and the second electrode 330 can be a transparent electrode made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML). The light generated by the light-emitting unit 320 can be emitted through the second electrode 330. The light-emitting unit 320 can have a multi-layer structure. For example, the light-emitting unit 320 can further include at least one of a hole injection layer (HIL), a hole transport layer (HTL), an electron transport layer (ETL) and an electron injection layer (EIL).

The bank insulating layer 160 can be disposed on the device planarization layer 150. The bank insulating layer 160 can include an insulating material. For example, the bank insulating layer 160 can be an organic insulating layer made of an organic insulating material. The first electrode 310 of each pixel area PA can be insulated from the first electrode 310 of adjacent pixel area PA by the bank insulating layer 160. For example, an edge of the first electrode 310 in each pixel area PA can be covered by the bank insulating layer 160. The bank insulating layer 160 can partially expose the first electrode 310 of each pixel area PA. For example, an emission area R-EA, G-EA and B-EA can be defined in each pixel area PA by the bank insulating layer 160.

The light-emitting unit 320 of each pixel area PA can be in direct contact with a portion of the first electrode 310 exposed by the bank insulating layer 160 and the second electrode 330 on the corresponding pixel area PA. For example, the emission area R-EA, G-EA and B-EA of each pixel area PA can be an area where light is generated. An area disposed between the emission areas R-EA, G-EA and B-EA can be a non-emission area where light is not generated. For example, in the display apparatus according to the embodiment of the present disclosure, a red emission area R-EA can be defined in the red pixel area R-PA by the bank insulating layer 160, a green emission area G-EA can be defined in the green pixel area G-PA by the bank insulating layer 160, and a blue emission area B-EA can be defined in the blue pixel area B-PA by the bank insulating layer 160.

The light generated by the light-emitting unit 320 of each pixel area PA can display a different color from the light generated by the light-emitting unit 320 of adjacent pixel area PA. For example, in the display apparatus according to the embodiment of the present disclosure, the light-emitting unit 320 of the red pixel area R-PA can include a red emission material layer, the light-emitting unit 320 of the green pixel area G-PA can include a green emission material layer, and the light-emitting unit 320 of the blue pixel area B-PA can include a blue emission material layer. The light-emitting unit 320 of each pixel area PA can be spaced apart from the light-emitting unit 320 of adjacent pixel area PA on the bank insulating layer 160.

A signal applied to the second electrode 330 of each pixel area PA can be a same as a signal applied to the second electrode 330 of adjacent pixel area PA. For example, a second power voltage can be applied to the second electrode 330 of each pixel area PA. The second power voltage can be different from the first power voltage. For example, the first power voltage can be a positive power voltage (VDD), and the second power voltage can be a negative power voltage (VSS). The second electrode 330 of each pixel area PA can be electrically connected to the second electrode 330 of adjacent pixel area PA. The second electrode 330 of each pixel area PA can exist simultaneously with the second electrode 330 of adjacent pixel area PA. For example, the second electrode 330 of each pixel area PA can be in direct contact with the second electrode 330 of adjacent pixel area PA. Thus, in the display apparatus according to the embodiment of the present disclosure, a process of forming the second electrode 330 of each pixel area PA can be simplified.

An encapsulation structure 400 can be disposed on the light-emitting device 300 of each pixel area PA. The encapsulation structure 400 can prevent the damage of the light-emitting device 300 in each pixel area PA due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a material having a higher fluidity than the first encapsulating layer 410 and the third encapsulating layer 430. For example, the first encapsulating layer 410 and the third encapsulating layer 430 can be an inorganic encapsulating layer made of an inorganic insulating material, and the second encapsulating layer 420 can be an organic encapsulating layer made of an organic insulating material. A thickness difference due to the light-emitting device 300 of each pixel area PA can be removed by the second encapsulating layer 420.

Pixel lenses 500 can be disposed on the encapsulation structure 400. The pixel lenses 500 can overlap with the emission areas R-EA, G-EA and B-EA of the pixel areas PA. The pixel lens 500 of each pixel area PA can function as a convex lens. For example, a surface of each pixel lens 500 opposite to the device substrate 100 can have a convex shape. The pixel lens 500 of each pixel area PA can be in direct contact with the encapsulation structure 400. For example, a lower surface of each pixel lens 500 toward the device substrate 100 can be in direct contact with an upper surface of the encapsulation structure 400 opposite to the device substrate 100. The pixel lens 500 of each pixel area PA can have a larger size than the emission area R-EA, G-EA and B-EA of the corresponding pixel area PA. Thus, in the display apparatus according to the embodiment of the present disclosure, the light extraction efficiency of each pixel area PA can be increased.

A lens planarization layer 600 can be disposed on the pixel lens 500 of each pixel area PA. The lens planarization layer 600 can prevent the damage of the pixel lenses 500 due to the external impact. For example, the pixel lens 500 of each pixel area PA can be completely covered by the lens planarization layer 600. The lens planarization layer 600 can include an insulating material. The lens planarization layer 600 can include a transparent material. For example, the lens planarization layer 600 can be an inorganic insulating layer made of an organic insulating material. A thickness difference due to the pixel lens 500 of each pixel area PA can be removed by the lens planarization layer 600. For example, an upper surface of the lens planarization layer 600 opposite to the device substrate 100 can have a curvature. The lens planarization layer 600 can have a refractive index smaller than the pixel lens 500 of each pixel area PA. Thus, in the display apparatus according to the embodiment of the present disclosure, the light passing through the pixel lens 500 of each pixel area PA can be refracted at a boundary between the corresponding pixel lens 500 and the lens planarization layer 600.

Color filters 700R, 700G and 700B can be disposed on the lens planarization layer 600. The color filters 700R, 700G and 700B can overlap with the pixel lenses 500. For example, each of the color filters 700R, 700G and 700B can overlap with the emission area R-EA, G-EA and B-EA of one of the pixel areas PA. Each of the color filters 700R, 700G and 700B can include a different material from adjacent color filter 700R, 700G and 700B. For example, the color filters 700R, 700G and 700B can include a red color filter 700R overlapping with the red emission area R-EA, a green color filter 700G overlapping with the green emission area G-EA and a blue color filter 700B overlapping with the blue emission area B-EA. Thus, in the display apparatus according to the embodiment of the present disclosure, the color reproduction of each pixel area PA can be improved.

A barrier pattern 710 may be disposed on a same layer as the color filter (e.g., the lens planarization layer 600 in FIG. 5). A barrier pattern 710 can be disposed between the color filters 700R, 700G and 700B. For example, the barrier pattern 710 can overlap with the non-emission area. The barrier pattern 710 can include a material capable of blocking light. For example, the barrier pattern 710 can include a black dye, such as carbon black. Thus, in the display apparatus according to the embodiment of the present disclosure, the light that does not pass through the color filters 700R, 700G and 700B cannot be emitted outside. Therefore, in the display apparatus according to the embodiment of the present disclosure, the light leakage can be prevented. And, in the display apparatus according to the embodiment of the present disclosure, the unintended color mixing can be prevented by the barrier pattern 710.

A filter planarization layer 800 can be disposed on the color filters 700R, 700G and 700B. The filter planarization layer 800 can prevent the damage of the color filters 700R, 700G and 700B due to the external impact. The filter planarization layer 800 can include an insulating material. For example, the filter planarization layer 800 can be an organic insulating layer made of an organic insulating material. The filter planarization layer 800 can include a same material as the lens planarization layer 600. For example, a refractive index of the filter planarization layer 800 can be a same as a refractive index of the lens planarization layer 600. A thickness difference due to the color filters 700R, 700G and 700B can be removed by the filter planarization layer 800. For example, an upper surface of the filter planarization layer 800 opposite to the device substrate 100 can extend parallel to the upper surface of the lens planarization layer 600.

The light generated by the light-emitting device 300 of each pixel area PA can be emitted outside through the pixel lens 500 and the color filter 700R, 700G and 700B of the corresponding pixel area PA. For example, the upper surface of the filter planarization layer 800 can be in direct contact with the atmosphere. Thus, in the display apparatus according to the embodiment of the present disclosure, the light passing through the filter planarization layer 800 can be refracted at the upper surface of the filter planarization layer 800 by a difference in refractive index between the filter planarization layer 800 and the atmosphere. A difference in refractive index between the pixel lens 500 of each pixel area PA and the encapsulation structure 400 can be smaller than a difference in refractive index between the pixel lens 500 of each pixel area PA and the lens planarization layer 600. A difference in refractive index between the color filter 700R, 700G and 700B of each pixel area PA and the lens planarization layer 600 and a difference in refractive index between the color filter 700R, 700G and 700B of each pixel area PA and the filter planarization layer 800 can be smaller than the difference in refractive index between the pixel lens 500 of each pixel area PA and lens planarization layer 600. That is, in the display apparatus according to the embodiment of the present disclosure, the light emitted from the light-emitting device 300 of each pixel area PA can be firstly refracted at a boundary between the pixel lens 500 of the corresponding pixel area PA and the lens planarization layer 600, and secondly refracted at the upper surface of the filter planarization layer 800.

If the center of the pixel lens 500 in each pixel area PA is disposed on a path of the light obliquely emitted from the light-emitting device 300 of the corresponding pixel area PA with respect to a virtual line VL perpendicular to the upper surface of the device substrate 100, the light emitted from the light-emitting device 300 of each pixel area PA can be refracted between the pixel lens 500 of the corresponding pixel area PA and the lens planarization layer 600 while satisfying a following equation 1. (Herein, n1 is a refractive index of the pixel lens 500 on each pixel area PA, n2 is a refractive index of the lens planarization layer 600, θ1 is a first angle between the virtual line VL and a travelling direction of the light emitted from the light-emitting device 300 of each pixel area PA, and θ2 is a second angle between the virtual line VL and a traveling direction of light refracted at the boundary between the pixel lens 500 of each pixel area PA and the lens planarization layer 600)

$${n}_{1} sin {θ}_{1} = {n}_{2} sin {θ}_{2} \qquad [ equation 1 ]$$

And, since the refractive index of the atmosphere is 1, the light refracted at the boundary between the pixel lens 500 of each pixel area PA and the lens planarization layer 600 can be refracted at the upper surface of the filter planarization layer 800 in a direction satisfying a following equation 2. (Herein, θ3 is a third angle between the virtual line VL and a traveling direction of the light refracted at the upper surface of the filter planarization layer 800)

$${n}_{2} sin {θ}_{2} = sin {θ}_{3} \qquad [ equation 2 ]$$

That is, in the display apparatus according to the embodiment of the present disclosure, the light emitted from the light-emitting device 300 of each pixel area PA in a direction of the first angle θ1 with respect to the virtual line VL and passing through the upper surface of the filer planarization layer 800 can travel in a direction of the third angle θ3 with respect to the virtual line VL satisfying a following equation 3, when the center 500c of the pixel lens 500 in each pixel area PA is disposed on a path of the light emitted from the light-emitting device 300 of the corresponding pixel area PA in a direction of the first angle θ1 with respect to the virtual line VL.

$${θ}_{1} = asin ( \frac{1}{{n}_{1}} sin {θ}_{3} ) \qquad [ equation 3 ]$$

In the display apparatus according to the embodiment of the present disclosure, the light emitted from the light-emitting device 300 of each pixel area PA through the pixel lens 500 and the color filter 700R, 700G and 700B of the corresponding pixel area PA can be parallel to the light emitted from the light-emitting device 300 of adjacent pixel area PA through the pixel lens 500 and the color filter 700R, 700G and 700B of adjacent pixel area PA, when the third angle θ3 of the light emitted from the light-emitting device 300 of each pixel area PA and passing through the upper surface of the filter planarization layer 800 with respect to the virtual line VL is equal to the central angle θ, between the center of the display panel DP and the corresponding pixel area PA (e.g., the center 300c of the light-emitting device 300), with respect to the curvature center of the curvature of the display panel. Therefore, in the display apparatus according to the embodiment of the present disclosure, the light emitted from the pixel areas PA of the display panel DP can be parallel light, when the first angle θ1 of the light emitted from the light-emitting device 300 of each pixel area PA with respect to the virtual line VL satisfies a following equation 4, the center 500c of the pixel lens 500 on each pixel area PA is disposed on a path of the light emitted from the light-emitting device 300 of the corresponding pixel area PA, and the color filter 700R, 700G and 700B of each pixel area PA is disposed on a path of the light refracted between the pixel lens 500 of the corresponding pixel area PA and the lens planarization layer 600.

$${θ}_{1} = asin ( \frac{1}{{n}_{1}} sin θ ) \qquad [ equation 4 ]$$

Accordingly, the display apparatus according to the embodiment of the present disclosure can the display panel DP having a non-zero curvature (cf. FIG. 2, in which a curvature center of the curvature is shown), wherein the display panel DP can include the light-emitting devices 300, the pixel lenses 500 and the color filters 700R, 700G and 700B stacked on the pixel areas PA, wherein the center 500c of the pixel lens 500 on each pixel area PA can be disposed on a path of the light emitted from the light-emitting device 300 of the corresponding pixel area PA at the first angle θ1 satisfying the equation 4, and wherein the color filter 700R, 700G and 700B of each pixel area PA can be disposed on a path of the light refracted between the pixel lens 500 of the corresponding pixel area PA and the lens planarization layer 600. That is, in the display apparatus according to the embodiment of the present disclosure, a distance (also referred as “a first distance”) between the center 300c of the light-emitting device 300 and the center 500c of the pixel lens 500 in each pixel area PA along a surface of the display panel DP can be determined by a distance (also referred as “a second distance”) between the center of the display panel DP and the center 300c of the light-emitting device 300 along the surface of the display panel DP. For example, for a plurality of light-emitting devices of the display panel of the present disclosure, in the cross-section shown in FIG. 2, the first distance increases with the increase of the second distance. Thus, in the display apparatus according to the embodiment of the present disclosure, the light emitted from each pixel area PA of the display panel DP can be provided parallel to the user. Therefore, in the display apparatus according to the embodiment of the present disclosure, the distortion of the image realized by the display panel DP having a curvature according to a viewing angle can be improved. In addition, the display panel according to the present disclosure includes a central pixel area (e.g., the middle pixel area in FIG. 4) at the center of the display panel and non-central pixel areas not located at the center of the display panel (e.g., pixel areas PAs in FIG. 5). In FIG. 5, for each of the non-central pixel areas, a center of the color filter on the non-central pixel area is spaced apart from the virtual line passing through a center of a light-emitting device of the non-central pixel area and a center of the pixel lens of the non-central pixel area.

And, in the display apparatus according to the embodiment of the present disclosure, the distortion of the image according to a viewing angle can be improved by relative positions of the light-emitting device 300 and the pixel lens 500 of each pixel area PA. Thus, in the display apparatus according to the embodiment of the present disclosure, the distortion of the image realized by the display panel DP having a curvature according to a viewing angle can be improved without the addition of the process. Therefore, in the display apparatus according to the embodiment of the present disclosure, the production energy can be reduced by process optimization.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a plurality of switching thin film transistors. For example, in the display apparatus according to another embodiment of the present disclosure, the driving circuit DC of each pixel area PA can further include a third thin film transistor to initialize the storage capacitor Cst according to the gate signal. The signal wirings GL, DL and PL can include an initial line applying a signal to the initialization of the storage capacitor Cst. Thus, in the display apparatus according to another embodiment of the present disclosure, the degree of freedom in the configuration of the driving circuit DC in each pixel area PA can be improved.

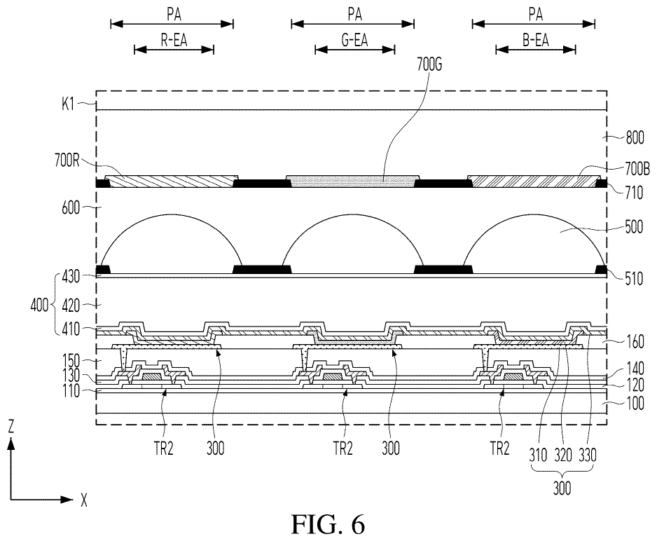

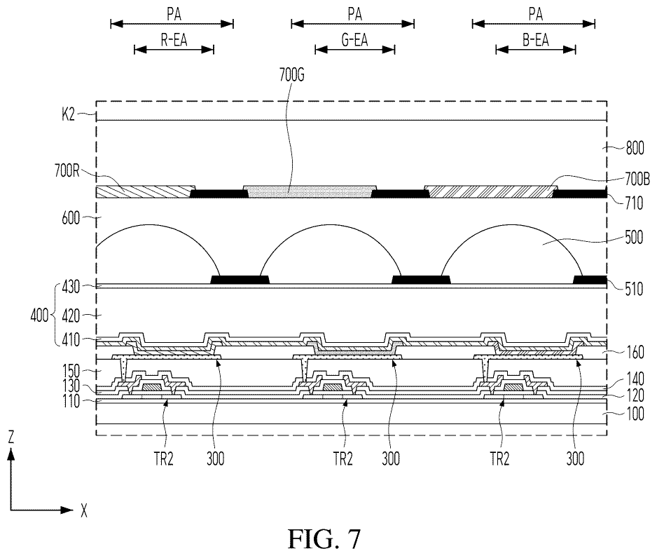

The display apparatus according to the embodiment of the present disclosure is described that the barrier pattern 710 is disposed between the color filters 700R, 700G and 700B. However, in the display apparatus according to another embodiment of the present disclosure, the barrier pattern 710 can be disposed at various locations. And, in the display apparatus according to another embodiment of the present disclosure, a plurality of barrier patterns 710 can be used. For example, in the display apparatus according to another embodiment of the present disclosure, a lower barrier pattern 510 overlapping with the bank insulating layer 160 between the encapsulation structure 400 and the lens planarization layer 600 and an upper barrier pattern 710 overlapping with the lower barrier pattern 510 between the lens planarization layer 600 and the filter planarization layer 800, as shown in FIGS. 6 and 7. The display panel includes a plurality of color filters and a plurality of upper barrier patterns disposed on the lens planarization layer. The display panel further includes an encapsulation structure on which the pixel lens and a plurality of lower barrier patterns are disposed. The display panel includes a central pixel area at the center of the display panel and non-central pixel areas not located at the center of the display panel. In FIG. 6, for an upper barrier pattern for the central pixel area among the plurality of upper barrier patterns and a lower barrier pattern for the central pixel area among the plurality of lower barrier patterns, the upper barrier pattern is disposed to be aligned with the lower barrier pattern. In FIG. 7, for an upper barrier pattern for one of the non-central pixel areas among the plurality of upper barrier patterns and a lower barrier pattern for the one of the non-central pixel areas among the plurality of lower barrier patterns, the upper barrier pattern is set to be offset from the lower barrier pattern. Thus, in the display apparatus according to another embodiment of the present disclosure, the light leakage and the unintended color mixing can be effectively prevented. Therefore, in the display apparatus according to the embodiment of the present disclosure, the degree of freedom in the configuration of the display panel DP can be improved.

In the result, the display apparatus according to the embodiments of the present disclosure can comprise the display panel having a curvature, wherein the display panel can include the light-emitting devices and the pixel lenses stacked in the pixel areas PA, wherein a distance between the center of the light-emitting device and the center of the pixel lens in each pixel area along a surface of the display panel can be determined by a distance between the center of the display panel and the center of the light-emitting device along the surface of the display panel. Thus, in the display apparatus according to the embodiments of the present disclosure, the light emitted from the light-emitting device of each pixel area through the pixel lens of the corresponding pixel area can be parallel to the light emitted from the light-emitting device of adjacent pixel area through the pixel lens of adjacent pixel area. Thereby, in the display apparatus according to the embodiments of the present disclosure, the distortion of the image according to a viewing angle due to the curvature of the display panel can be improved. And, in the display apparatus according to the embodiments of the present disclosure, the production energy can be reduced by process optimization.

What is claimed is:

1. A display apparatus comprising:
a display panel comprising a light-emitting device and a pixel lens stacked in each pixel area,
wherein the display panel has a non-zero curvature, and
wherein the light-emitting device and the pixel lens in each pixel area are configured such that a distance between a center of the light-emitting device and a center of the pixel lens along a surface of the display panel is determined by a distance between a center of the display panel and the center of the light-emitting device along the surface of the display panel so that a light emitted from the light-emitting device in the pixel area through the pixel lens is parallel to the light emitted from a light-emitting device in an adjacent pixel area adjacent to the pixel area through a pixel lens of the adjacent pixel area.

2. The display apparatus according to claim 1, wherein the display panel comprises a device substrate supporting the light-emitting device and the pixel lens of each pixel area, and
wherein, for each pixel area, a central angle θ, between a center of the display panel and the center of the light-emitting device in the pixel area, with respect to a curvature center of the curvature, and a first angle θ1, between a connecting line between the center of the light-emitting device and the center of the pixel lens in the pixel area and a virtual line passing through the center of the light-emitting device and perpendicular to an upper surface of the device substrate, satisfy a following equation:
$${θ}_{1} = asin ( \frac{1}{{n}_{1}} sin θ )$$
wherein, n1 is a refractive index of the pixel lens in the pixel area.

3. The display apparatus according to claim 1, wherein the display panel comprises a lens planarization layer disposed on the pixel lens of each pixel area, and
wherein the lens planarization layer has a refractive index smaller than the pixel lens of each pixel area.

4. The display apparatus according to claim 3, wherein the display panel comprises an encapsulation structure between the light-emitting device and the pixel lens of each pixel area, and
wherein a difference in refractive index between the pixel lens of each pixel area and the encapsulation structure is smaller than a difference in refractive index between the pixel lens of each pixel area and the lens planarization layer.

5. The display apparatus according to claim 3, wherein the display panel further comprises a color filter on the pixel lens of each pixel area, and
wherein a difference in refractive index between the color filter of each pixel area and the lens planarization layer is smaller than a difference in refractive index between the pixel lens of each pixel area and the lens planarization layer.

6. The display apparatus according to claim 5, wherein the display panel comprises a central pixel area located at the center of the display panel and non-central pixel areas not located at the center of the display panel, and
wherein, for each of the non-central pixel areas, a center of the color filter on the non-central pixel area is spaced apart from a virtual line passing through a center of a light-emitting device of the non-central pixel area and a center of the pixel lens of the non-central pixel area.

7. The display apparatus according to claim 5, wherein the display panel comprises a filter planarization layer covering the color filter of each pixel area on the lens planarization layer, and
wherein a difference in refractive index between the color filter of each pixel area and the filter planarization layer is smaller than a difference in refractive index between the pixel lens of each pixel area and the lens planarization layer.

8. The display apparatus according to claim 7, wherein a refractive index of the filter planarization layer is same as a refractive index of the lens planarization layer.

9. The display apparatus according to claim 1, wherein the display panel comprises a bank insulating layer defining an emission area in each pixel area and a barrier pattern disposed on the bank insulating layer, and
wherein the light-emitting device and the pixel lens of each pixel area overlap with the emission area of the pixel area.

10. The display apparatus according to claim 9, wherein the barrier pattern is disposed on a same layer as the pixel lens of each pixel area.

11. The display apparatus according to claim 9, wherein the display panel further comprises a color filter on the pixel lens of each pixel area, and
wherein the barrier pattern is disposed on a same layer as the color filter.

12. The display apparatus according to claim 3, wherein the display panel comprises a plurality of color filters and a plurality of upper barrier patterns disposed on the lens planarization layer, and
wherein the display panel further comprises an encapsulation structure on which the pixel lens and a plurality of lower barrier patterns are disposed.

13. The display apparatus according to claim 12, wherein the display panel comprises a central pixel area located at the center of the display panel and non-central pixel areas not located at the center of the display panel,
wherein, for an upper barrier pattern for the central pixel area among the plurality of upper barrier patterns and a lower barrier pattern for the central pixel area among the plurality of lower barrier patterns, the upper barrier pattern is disposed to be aligned with the lower barrier pattern, and
wherein, for an upper barrier pattern for one of the non-central pixel areas among the plurality of upper barrier patterns and a lower barrier pattern for the one of the non-central pixel areas among the plurality of lower barrier patterns, the upper barrier pattern is set to be offset from the lower barrier pattern.

14. A display apparatus comprising:
a display panel comprising a light-emitting device and a pixel lens stacked in each pixel area, the display panel having a non-zero curvature,
wherein, for a plurality of light-emitting devices of the display panel, a first distance increases with the increase of a second distance,
wherein a first distance is a distance between a center of the light-emitting device and a center of the pixel lens of the light-emitting device along a surface of the display panel, and
wherein a second distance is a distance between a center of the display panel and the center of the light-emitting device along a surface of the display panel.

15. The display apparatus of claim 14, wherein the pixel lens of the light-emitting device is positioned such that a light emitted from the light-emitting device in the pixel area through the pixel lens is parallel to a light emitted from a light-emitting device in an adjacent pixel area adjacent to the pixel area through a pixel lens of the adjacent pixel area.
